(19) United States
(12) Patent Application Publication
(10) Pub. No.: US 2024/0170473 A1
(43) Pub. Date: May 23, 2024

(54) CHIP PACKAGE STRUCTURE AND MANUFACTURING METHOD THEREOF

(71) Applicant: Industrial Technology Research Institute, Hsinchu (TW)

(72) Inventors: Hao-Che Kao, Taipei City (TW); Wen-Hung Liu, Taichung City (TW); Yu-Min Lin, Hsinchu County (TW); Ching-Kuan Lee, Yunlin County (TW)

(73) Assignee: Industrial Technology Research Institute, Hsinchu (TW)

(21) Appl. No.: 18/347,594

(22) Filed: Jul. 6, 2023

(30) Foreign Application Priority Data
Nov. 23, 2022 (TW) 111144711
Apr. 14, 2023 (TW) 112114034

(51) Int. Cl. H01L 25/00; H01L 21/56; H01L 21/683; H01L 23/00; H01L 23/31; H01L 23/373; H01L 23/498; H01L 25/065

(52) U.S. Cl. CPC H01L 25/50; H01L 21/561; H01L 21/568; H01L 21/6836; H01L 23/3121; H01L 23/3735; H01L 23/49822; H01L 24/29; H01L 24/32; H01L 24/33; H01L 24/83; H01L 24/95; H01L 25/0655; H01L 21/4853; H01L 24/16; H01L 24/73; H01L 2221/68381; H01L 2224/16227; H01L 2224/29111; H01L 2224/2919; H01L 2224/32245; H01L 2224/33181; H01L 2224/33505; H01L 2224/73204; H01L 2224/73253; H01L 2924/0665

(57) ABSTRACT

A chip package structure including a heat dissipation base, a first redistribution layer, a second redistribution layer, at least one chip, at least one metal stack, a plurality of conductive structures, and an encapsulant is provided. The second redistribution layer is disposed on the heat dissipation base and thermally coupled to the heat dissipation base. The chip, the metal stack, and the conductive structures are disposed between the second redistribution layer and the first redistribution layer. An active surface of the chip is electrically connected to the first redistribution layer and an inactive surface of the chip is thermally coupled to the second redistribution layer via the metal stack. The first redistribution layer is electrically connected to the second redistribution layer via the conductive structures. The encapsulant is filled between the second redistribution layer and the first redistribution layer. A manufacturing method of a chip package structure is also provided.

### CROSS-REFERENCE TO RELATED APPLICATION

This application claims the priority benefits of Taiwan application no. 111144711, filed on Nov. 23, 2022, and Taiwan application no. 112114034, filed on Apr. 14, 2023. The entirety of each of the above-mentioned patent applications is hereby incorporated by reference herein and made a part of this specification.

### TECHNICAL FIELD

The disclosure relates to a chip package structure.

### BACKGROUND

With the rapid development of semiconductor techniques, the density and performance of integrated circuits continue to increase. Correspondingly, integrated circuits generate a large amount of heat during operation, and once the heat may not be dissipated quickly, the performance of the integrated circuits is decreased significantly. Under the action of thermal stress, integrated circuit packages are prone to warping, delamination, or cracking, resulting in poor electrical properties and reliability of the integrated circuits.

Moreover, the development of the integrated circuit packages towards miniaturization and high integration is the current trend. Taking the system-in-package (SiP) integrating a plurality of chips of different functions and different sizes into the same package as an example, during the process, a plurality of chips having different sizes are not conducive to grabbing and transferring onto the corresponding circuits, thus not only affecting process efficiency, but also affecting process reliability (such as misalignment).

### SUMMARY

An embodiment of the disclosure provides a chip package structure including a heat dissipation base, a first redistribution layer, a second redistribution layer, a plurality of chips, a plurality of metal stacks, a plurality of conductive structures, and an encapsulant. The second redistribution layer is disposed on the heat dissipation base and thermally coupled to the heat dissipation base. The second redistribution layer is located between the first redistribution layer and the heat dissipation base. The plurality of chips are disposed between the second redistribution layer and the first redistribution layer, and have different thicknesses. Each of the chips has an active surface facing the first redistribution layer and an inactive surface facing the second redistribution layer, and the plurality of active surfaces of the plurality of chips are electrically connected to the second redistribution layer. The plurality of metal stacks are disposed between the second redistribution layer and the plurality of inactive surfaces of the plurality of chips, wherein the plurality of inactive surfaces of the plurality of chips are thermally coupled to the second redistribution layer via the plurality of metal stacks, and the plurality of metal stacks have different thicknesses. The plurality of conductive structures are disposed between the second redistribution layer and the first redistribution layer and electrically connected to the second redistribution layer and the first redistribution layer. Each of the conductive structures includes a metal inner core and a metal outer layer covering the metal inner core, and the metal inner core is partially exposed to the metal outer layer to be in contact with the second redistribution layer. The encapsulant is filled between the second redistribution layer and the first redistribution layer.

An embodiment of the disclosure provides a manufacturing method of a chip package structure, including: forming a plurality of metal stacks on a first carrier; providing a plurality of chips having different sizes, wherein each of the chips has an active surface and an inactive surface opposite to the active surface, and the plurality of inactive surfaces of the plurality of chips are bonded to the plurality of metal stacks; grinding a side of the first carrier opposite to the plurality of metal stacks, and cutting the first carrier to form a plurality of sacrificial layers bonded to the plurality of metal stacks, wherein the plurality of sacrificial layers have a same size; forming a first redistribution layer on a second carrier; transferring the corresponding metal stack and chip onto the first redistribution layer via each of the sacrificial layers, and bonding the plurality of active surfaces of the plurality of chips to the first redistribution layer; forming a plurality of conductive structures on the first redistribution layer, wherein each of the conductive structures includes a metal inner core and a metal outer layer covering the metal inner core; forming an encapsulant on the first redistribution layer to cover the plurality of chips, the plurality of metal stacks, the plurality of sacrificial layers, and the plurality of conductive structures; grinding a side of the encapsulant opposite to the first redistribution layer and removing the plurality of sacrificial layers, partially removing the plurality of metal stacks, and partially removing the metal inner core and the metal outer layer of each of the conductive structures, so that the metal stacks have different thicknesses, and partially exposing the metal inner core of each of the conductive structures to the metal outer layer; forming the second redistribution layer on the encapsulant so that the plurality of metal stacks are thermally coupled to the second redistribution layer, and the metal inner core in each of the conductive structures exposed to the metal outer layer is in contact with the second redistribution layer; removing the second carrier; and bonding the heat dissipation base to a side of the second redistribution layer opposite to the encapsulant.

An embodiment of the disclosure provides a chip package structure including a heat dissipation base, a first redistribution layer, a second redistribution layer, a chip, a metal stack, a plurality of conductive structures, and an encapsulant. The second redistribution layer is disposed on the heat dissipation base and thermally coupled to the heat dissipation base. The second redistribution layer is located between the first redistribution layer and the heat dissipation base. The chip is disposed between the second redistribution layer and the first redistribution layer. The chip has an active surface facing the first redistribution layer and an inactive surface facing the second redistribution layer, and the active surface is electrically connected to the second redistribution layer. The metal stacks are disposed between the second redistribution layer and the inactive surface, and the inactive surface is thermally coupled to the second redistribution layer via the metal stacks. The plurality of conductive structures are disposed between the second redistribution layer and the first redistribution layer and electrically connected to the second redistribution layer and the first redistribution layer. Each of the conductive structures includes a metal inner core and a metal outer layer covering the metal inner core, and the metal inner core is partially exposed to the metal outer layer to be in contact with the second redistribution layer. The encapsulant is filled between the second redistribution layer and the first redistribution layer.

Several exemplary embodiments accompanied with figures are described in detail below to further describe the disclosure in details.

### BRIEF DESCRIPTION OF THE DRAWINGS

FIG. 1 to FIG. 12 are schematic cross-sectional views of a manufacturing process of a chip package structure of an embodiment of the disclosure.

FIG. 13 is a schematic top view of FIG. 9.

FIG. 14 is a schematic cross-sectional view of a chip package structure of another embodiment of the disclosure.

FIG. 15 is a schematic cross-sectional view of a chip package structure of another embodiment of the disclosure.

FIG. 16 is a schematic cross-sectional view of a chip package structure of another embodiment of the disclosure.

FIG. 17 is a schematic cross-sectional view of a chip package structure of another embodiment of the disclosure.

FIG. 18 is a schematic cross-sectional view of a chip package structure of another embodiment of the disclosure.

FIG. 19A is a schematic cross-sectional view of a chip package structure of another embodiment of the disclosure.

FIG. 19B is a partial schematic bottom view of FIG. 19A.

FIG. 20 is a schematic cross-sectional view of a chip package structure of another embodiment of the disclosure.

### DETAILED DESCRIPTION OF DISCLOSURE EMBODIMENTS

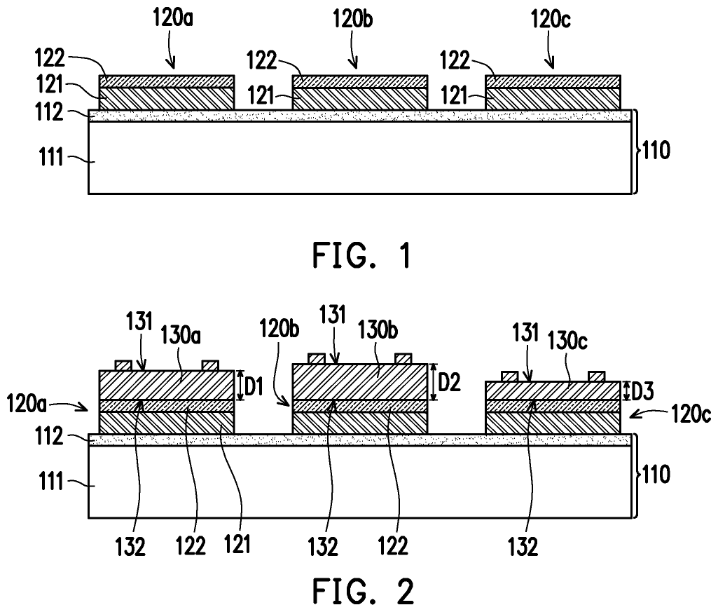

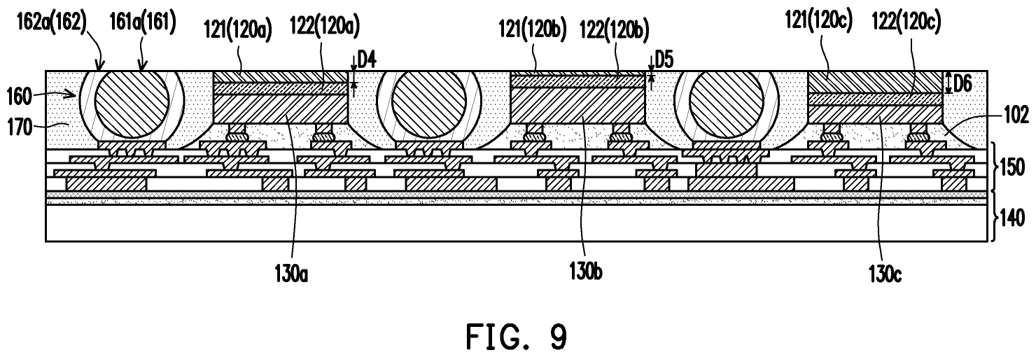

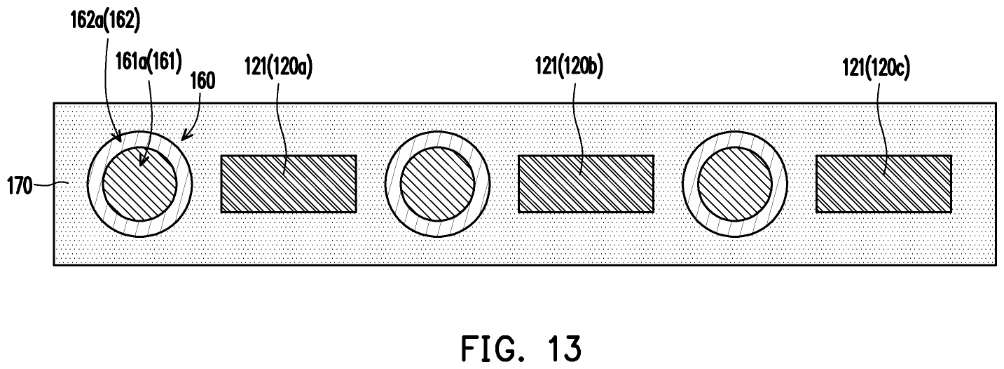

FIG. 1 to FIG. 12 are schematic cross-sectional views of a manufacturing process of a chip package structure of an embodiment of the disclosure. FIG. 13 is a schematic top view of FIG. 9. First, the pre-steps of chip transfer are performed. As shown in FIG. 1, a first carrier 110 is provided, including a carrier board 111 and a tape 112 attached on the carrier board 111. For example, the carrier board 111 may be a glass carrier board, and the tape 112 may be a wafer grinding tape. Next, a plurality of metal stacks separated from each other are formed on the tape 112 via a patterning process, and the plurality of metal stacks may include a first metal stack 120a, a second metal stack 120b, and a third metal stack 120c having the same thickness.

In the present embodiment, each of the metal stacks includes a first metal layer 121 and a second metal layer 122, wherein the first metal layer 121 may be a copper layer, and the second metal layer 122 may be a tin layer bonded onto the first metal layer 121. In each of the metal stacks, the thickness of the first metal layer 121 is greater than the thickness of the second metal layer 122, wherein the thickness of the first metal layer 121 of the first metal stack 120a, the thickness of the first metal layer 121 of the second metal stack 120b, and the thickness of the first metal layer 121 of the third metal stack 120c are equal, and the thickness of the second metal layer 122 of the first metal stack 120a, the thickness of the second metal layer 122 of the second metal stack 120b, and the thickness of the second metal layer 122 of the third metal stack 120c are equal.

Next, please refer to FIG. 2, a plurality of chips having different sizes are provided, and the plurality of chips are bonded to a plurality of metal stacks respectively. For example, the plurality of chips may be radio-frequency chips, power amplifiers, and antenna switches, but not limited thereto. More specifically, the plurality of chips include a first chip 130a, a second chip 130b, and a third chip 130c, wherein a thickness D1 of the first chip 130a is less than a thickness D2 of the second chip 130b, and greater than a thickness D3 of the third chip 130c. That is, the thickness D2 of the second chip 130b is the largest, and the thickness D3 of the third chip 130c is the smallest.

As shown in FIG. 1 and FIG. 2, each of the chips has an active surface 131 facing away from the first carrier 110 and an inactive surface 132 facing the first carrier 110. Further, the inactive surface 132 of the first chip 130a is bonded to the second metal layer 122 of the first metal stack 120a. The inactive surface 132 of the second chip 130b is bonded to the second metal layer 122 of the second metal stack 120b. The inactive surface 132 of the third chip 130c is bonded to the second metal layer 122 of the third metal stack 120c. That is, the second metal layer 122 of each of the metal stacks is located between the first metal layer 121 and the inactive surface 132 of the corresponding chip.

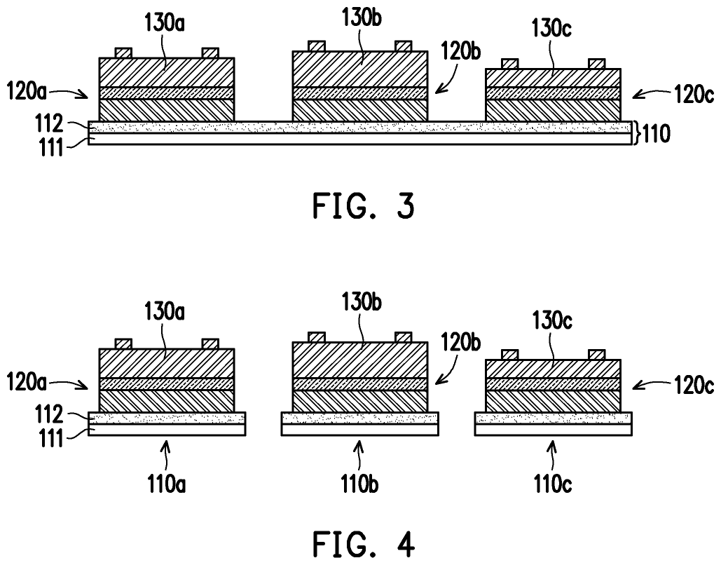

Next, referring to FIG. 3, the side of the first carrier 110 opposite to the plurality of metal stacks is ground via a chemical mechanical polishing process, that is, the side of the carrier board 111 opposite to the tape 112 is ground to thin the carrier board 111. Next, please refer to FIG. 3 and FIG. 4, the first carrier 110 is cut via a laser cutting technique to form a plurality of sacrificial layers bonded to the plurality of metal stacks. More specifically, the plurality of sacrificial layers include a first sacrificial layer 110a bonded to the first metal stack 120a, a second sacrificial layer 110b bonded to the second metal stack 120b, and a third sacrificial layer 110c bonded to the third metal stack 120c. The first sacrificial layer 110a, the second sacrificial layer 110b, and the third sacrificial layer 110c have the same size. For example, the first sacrificial layer 110a, the second sacrificial layer 110b, and the third sacrificial layer 110c may have the same thickness, the same width, and the same grab area (or grab size), to facilitate grabbing and transferring the first chip 130a, the second chip 130b, and the third chip 130c having different sizes.

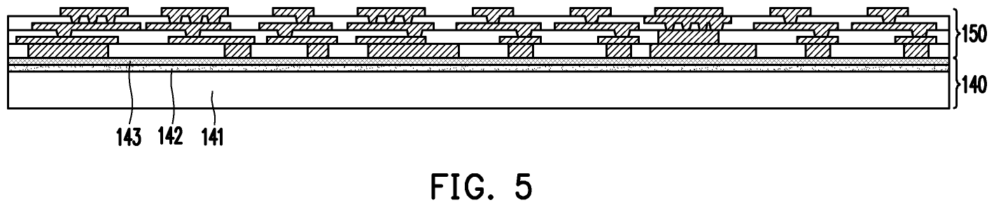

Next, please refer to FIG. 5, a second carrier 140 is provided. The second carrier 140 includes a carrier board 141, a temporary bonding material layer 142 formed on the carrier board 141, and a seed layer 143 formed on the temporary bonding material layer 142, and the carrier board 141 may be a glass carrier board. Next, a plurality of steps of forming a dielectric layer, drilling, exposing, developing, electroplating, and etching are performed repeatedly to form the first redistribution layer 150 on the seed layer 143.

Next, referring to FIG. 4 to FIG. 6, the corresponding metal stack and chip are transferred onto the first redistribution layer 150 via each of the sacrificial layers, and the active surface 131 of each of the chips is flip-chip bonded to the first redistribution layer 150 to be electrically connected to the first redistribution layer 150.

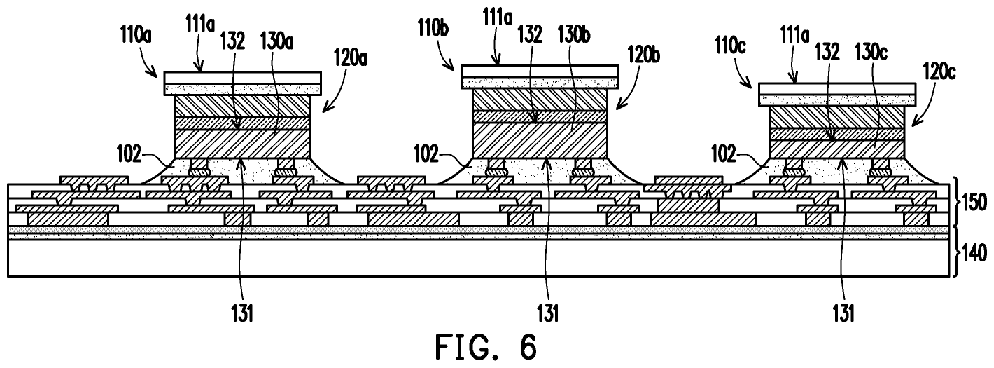

As shown in FIG. 6, in the present embodiment, each of the sacrificial layers has a surface 111a opposite to the corresponding metal stack, for example as a gripping surface. More specifically, the area of the surface 111a of the first sacrificial layer 110a is greater than the area of the inactive surface 132 of the first chip 130a, in order to facilitate grabbing the first chip 130a via the first sacrificial layer 110a to transfer the first chip 130a onto the first redistribution layer 150, so that the active surface 131 thereof is flip-chip bonded to the first redistribution layer 150.

Similarly, the area of the surface 111a of the second sacrificial layer 110b is greater than the area of the inactive surface 132 of the second chip 130b, in order to facilitate grabbing the second chip 130b via the second sacrificial layer 110b and transferring the second chip 130b onto the first redistribution layer 150, so that the active surface 131 thereof is flip-chip bonded to the first redistribution layer 150. Moreover, the area of the surface 111a of the third sacrificial layer 110c is greater than the area of the inactive surface 132 of the third chip 130c, in order to facilitate grabbing the third chip 130c via the third sacrificial layer 110c and transferring the third chip 130c onto the first redistribution layer 150, so that the active surface 131 thereof is flip-chip bonded to the first redistribution layer 150.

In other words, the sacrificial layers are used as an auxiliary tool for grabbing and transferring the chips, in order to facilitate improving the stability when grabbing the chips, and the chips are transferred onto the first redistribution layer 150 quickly and accurately, thus not only helping to improve process efficiency, but also helping to improve process reliability.

As shown in FIG. 6, after the active surface 131 of each of the chips is flip-chip bonded to the first redistribution layer 150, an underfill layer 102 is formed between the active surface 131 of each of the chips and the first redistribution layer 150. The underfill layer 102 is formed by curing the underfill adhesive, and the material may be epoxy resin. For example, the underfill adhesive is coated on the first redistribution layer 150 along the edge of the chip, and the underfill adhesive flows in between the active surface 131 of the chip and the first redistribution layer 150 by capillary action, so that the underfill adhesive covers the active surface 131 of the chip and covers the conductive features between the active surface 131 of the chip and the first redistribution layer 150, such as solder balls, pads, or solder joints. The underfill adhesive is heated to form the underfill layer 102 to improve the mechanical strength of solder balls, solder pads, or solder joints, and prevent the solder balls, the solder pads, or the solder joints from falling off or breaking due to stress, so as to improve the service life of the chip.

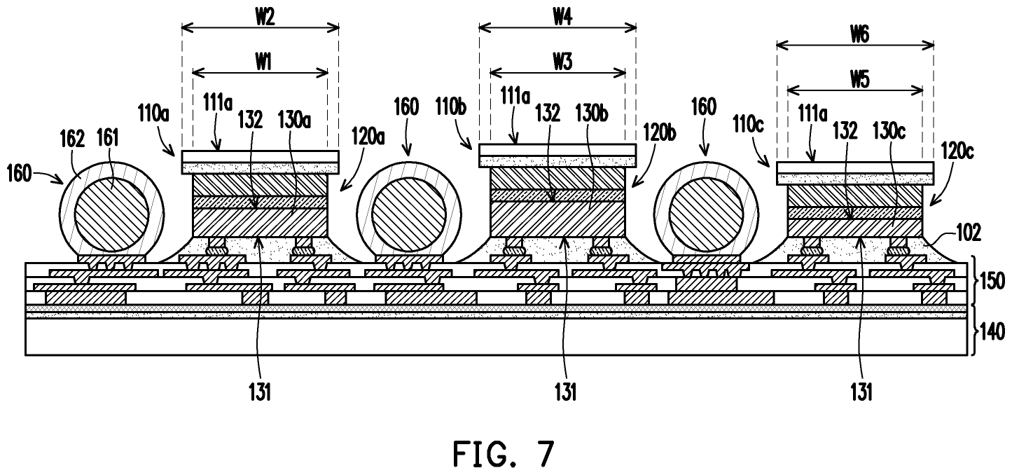

As shown in FIG. 7, the width of the first chip 130a and the width of the first metal stack 120a are W1, and a width W2 of the first sacrificial layer 110a is greater than the width W1, to facilitate grabbing and transferring the first chip 130a and the first metal stack 120a via the first sacrificial layer 110a. The width of the second chip 130b and the width of the second metal stack 120b are W3, and a width W4 of the second sacrificial layer 110b is greater than the width W3, to facilitate grabbing and transferring the second chip 130b and the second metal stack 120b via the second sacrificial layer 110b. The width of the third chip 130c and the width of the third metal stack 120c are W5, and a width W6 of the third sacrificial layer 110c is greater than the width W5, to facilitate grabbing and transferring the third chip 130c and the third metal stack 120c via the third sacrificial layer 110c.

For example, the area of the surface 111a of the first sacrificial layer 110a, the area of the surface 111a of the second sacrificial layer 110b, and the area of the surface 111a of the third sacrificial layer 110c are equal, and the width W2 of the first sacrificial layer 110a, the width W4 of the second sacrificial layer 110b, and the width W6 of the third sacrificial layer 110c are equal.

Next, please refer to FIG. 7, a plurality of conductive structures are formed on the first redistribution layer 150. In the present embodiment, the plurality of conductive structures may include a plurality of conductive balls 160. Each of the conductive balls 160 includes a metal inner core 161 and a metal outer layer 162 covering the metal inner core 161, wherein the material of the metal inner core 161 may be copper, and the material of the metal outer layer 162 may be tin. Since the conductive balls 160 have excellent heat resistance, they are not readily disintegrated by heat in subsequent process steps.

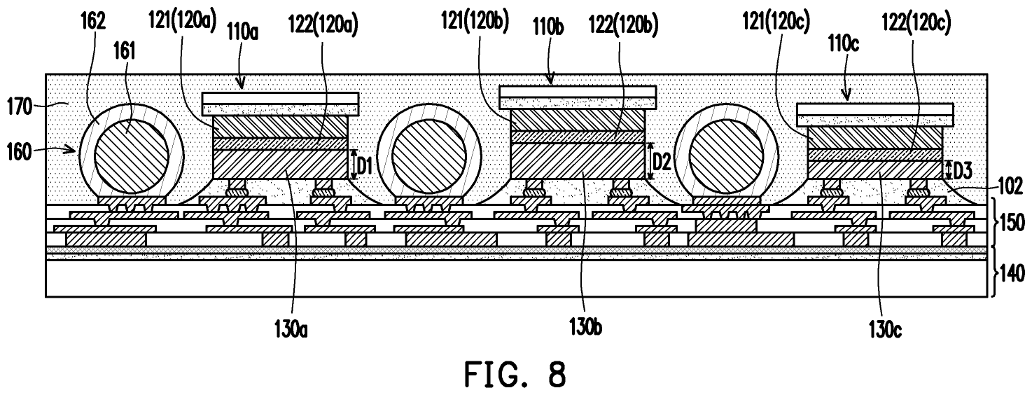

Next, referring to FIG. 8, an encapsulant 170 is formed on the first redistribution layer 150 to cover the first chip 130a, the second chip 130b, the third chip 130c, the first metal stack 120a, the second metal stack 120b, the third metal stack 120c, the first sacrificial layer 110a, the second sacrificial layer 110b, the third sacrificial layer 110c, and the plurality of conductive balls 160. For example, the encapsulant 170 may be formed by epoxy resin.

Next, referring to FIG. 8 and FIG. 9, the side of the encapsulant 170 opposite to the first redistribution layer 150 (that is, the side close to the first sacrificial layer 110a, the second sacrificial layer 110b, and the third sacrificial layer 110c) is ground via a chemical mechanical polishing process to partially remove the encapsulant 170, and the first sacrificial layer 110a, the second sacrificial layer 110b, and the third sacrificial layer 110c are completely removed.

After the first sacrificial layer 110a, the second sacrificial layer 110b, and the third sacrificial layer 110c are completely removed, the first metal layer 121 of the first metal stack 120a, the first metal layer 121 of the second metal stack 120b, and the first metal layer 121 of the third metal stack 120c are further ground to partially remove the first metal layer 121 of the first metal stack 120a, partially remove the first metal layer 121 of the second metal stack 120b, and partially remove the first metal layer 121 of the third metal stack 120c.

Please refer to FIG. 8 and FIG. 9, in the present embodiment, the removal amount of the first metal layer 121 of each of the metal stacks is determined by the thickness of the corresponding chip. Further, the thickness D2 of the second chip 130b is the largest, and the removal amount of the first metal layer 121 of the second metal stack 120b connected to the second chip 130b is the largest. In contrast, the thickness D3 of the third chip 130c is the smallest, and the removal amount of the first metal layer 121 of the third metal stack 120c connected to the third chip 130c is the smallest. Moreover, the thickness D1 of the first chip 130a is greater than the thickness D3 of the third chip 130c and less than the thickness D2 of the second chip 130b. Therefore, the removal amount of the first metal layer 121 of the first metal stack 120a connected to the first chip 130a is greater than the removal amount of the first metal layer 121 of the third metal stack 120c and less than the removal amount of the first metal layer 121 of the second metal stack 120b.

As shown in FIG. 9, after grinding, the thickness D4 of the first metal layer 121 of the second metal stack 120b is less than the thickness D5 of the first metal layer 121 of the first metal stack 120a, and the thickness D5 of the first metal layer 121 of the first metal stack 120a is less than the thickness D6 of the first metal layer 121 of the third metal stack 120c. That is, after grinding, the first metal stack 120a, the second metal stack 120b, and the third metal stack 120c have different thicknesses.

After grinding, the thickness difference between the first metal layer 121 of the first metal stack 120a, the first metal layer 121 of the second metal stack 120b, and the first metal layer 121 of the third metal stack 120c may be used to make up the thickness difference between the first chip 130a, the second chip 130b, and the third chip 130c, so that the total thickness of the first chip 130a and the first metal stack 120a, the total thickness of the second chip 130b and the second metal stack 120b, and the total thickness of the third chip 130c and the third metal stack 120c are equal.

Please refer to FIG. 8 and FIG. 9, after the first sacrificial layer 110a, the second sacrificial layer 110b, and the third sacrificial layer 110c are completely removed, the plurality of conductive balls 160 are further ground, and the metal inner core 161 and the metal outer layer 162 of each of the conductive balls 160 are partially removed, so that the metal inner core 161 is partially exposed to the metal outer layer 162.

Please refer to FIG. 9 and FIG. 13, after grinding, the metal outer layer 162 and the metal inner core 161 of each of the conductive balls 160 respectively form a first contact surface 162a and a second contact surface 161a. Further, in each of the conductive balls 160, the first contact surface 162a and the second contact surface 161a are coplanar, and the first contact surface 162a surrounds the second contact surface 161a.

Please refer to FIG. 8 and FIG. 9, before the grinding process, the first chip 130a, the second chip 130b, the third chip 130c, the first metal stack 120a, the second metal stack 120b, the third metal stack 120c, the first sacrificial layer 110a, the second sacrificial layer 110b, the third sacrificial layer 110c, and the plurality of conductive balls 160 are covered by the encapsulant 170. Therefore, during the grinding process, the encapsulant 170 may be used to eliminate or absorb the stress acting on the first chip 130a, the second chip 130b, and the third chip 130c, the stress acting on the first metal stack 120a, the second metal stack 120b, and the third metal stack 120c, and the stress acting on the plurality of conductive balls 160, to avoid damage to the package structure.

Please refer to FIG. 9, after grinding, the first metal layer 121 of the first metal stack 120a, the first metal layer 121 of the second metal stack 120b, and the first metal layer 121 of the third metal stack 120c are exposed to the encapsulant 170, and the first contact surface 162a of the metal outer layer 162 and the second contact surface 161a of the metal inner core 161 of each of the conductive balls 160 are exposed to the encapsulant 170.

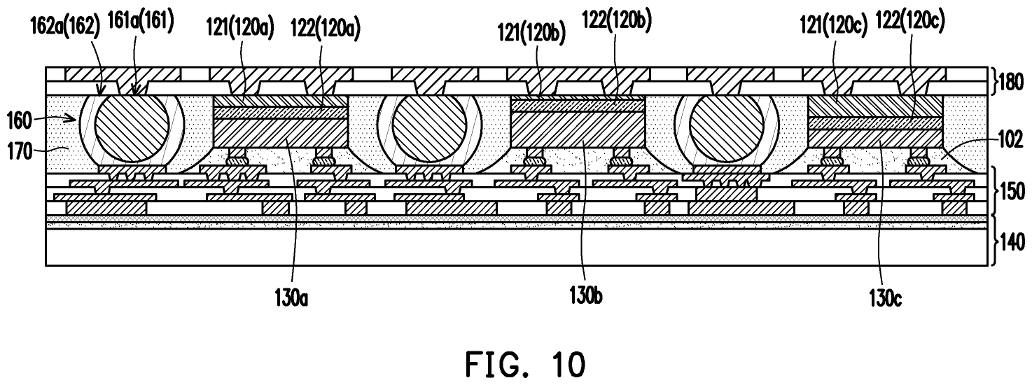

Next, referring to FIG. 10, the second redistribution layer 180 is formed on the encapsulant 170, so that the first metal stack 120a, the second metal stack 120b, and the third metal stack 120c are thermally coupled to the second redistribution layer 180, and the first contact surface 162a of the metal outer layer 162 and the second contact surface 161a of the metal inner core 161 of each of the conductive balls 160 are in contact with the second redistribution layer 180.

More specifically, the first metal stack 120a, the second metal stack 120b, and the third metal stack 120c are all in contact with the second redistribution layer 180 via the first metal layer 121. That is, the first metal layer 121 of each of the metal stacks is located between the second redistribution layer 180 and the corresponding second metal layer 122. Moreover, the second redistribution layer 180 is in contact with the first contact surface 162a of the metal outer layer 162 and the second contact surface 161a of the metal inner core 161 of each of the conductive balls 160, and electrically connected to the first redistribution layer 150 via the plurality of conductive balls 160.

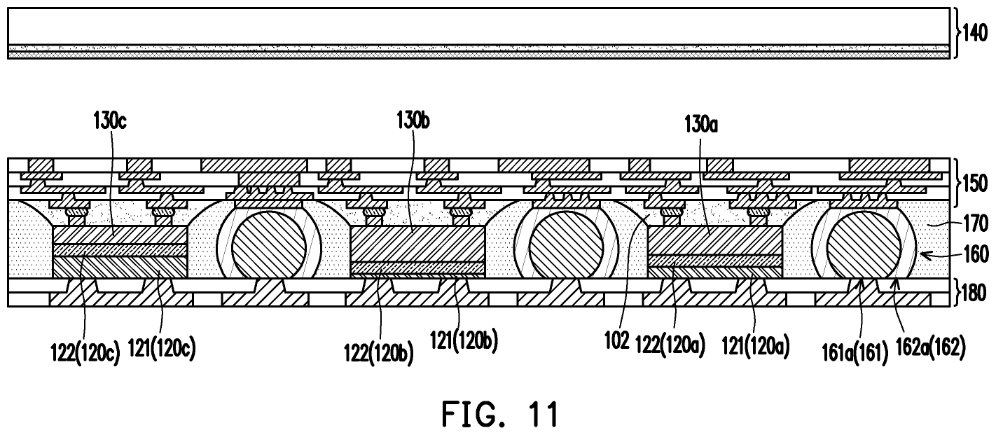

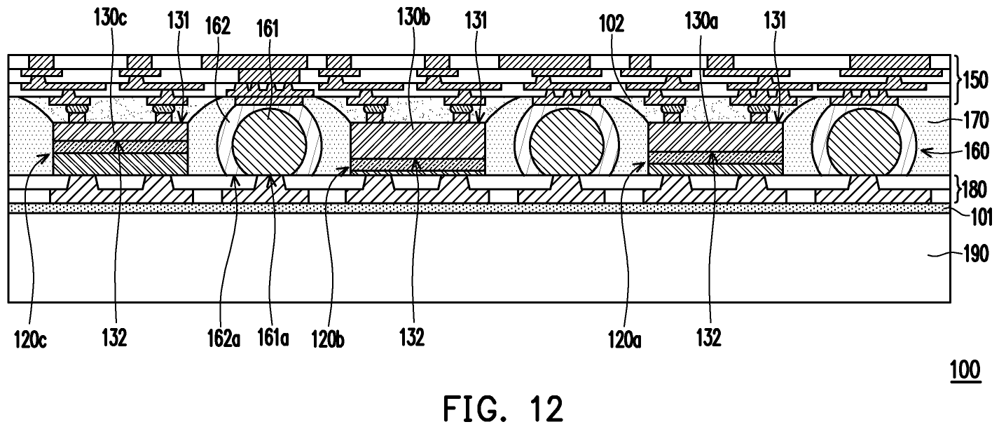

Next, referring to FIG. 11 and FIG. 12, the second carrier 140 is removed via a laser peeling process, and the heat dissipation base 190 is bonded to the side of the second redistribution layer 180 opposite to the encapsulant 170 via a thermocompression bonding process. For example, the heat dissipation base 190 may be a silicon substrate or a copper substrate, and is bonded to the second redistribution layer 180 via a thermal interface material 101.

Please refer to FIG. 12, in the chip package structure 100 of the present embodiment, the second redistribution layer 180 is disposed on the heat dissipation base 190 and thermally coupled to the heat dissipation base 190. The first redistribution layer 150 is disposed above the second redistribution layer 180, and the first chip 130a, the second chip 130b, the third chip 130c, the first metal stack 120a, the second metal stack 120b, the third metal stack 120c, and the plurality of conductive balls 160 are disposed between the second redistribution layer 180 and the first redistribution layer 150. The encapsulant 170 is filled between the second redistribution layer 180 and the first redistribution layer 150, and cover the first chip 130a, the second chip 130b, the third chip 130c, the first metal stack 120a, the second metal stack 120b, the third metal stack 120c, and the plurality of conductive balls 160.

The first chip 130a, the second chip 130b, and the third chip 130c are electrically connected to the first redistribution layer 150, and the first redistribution layer 150 is electrically connected to the second redistribution layer 180 via the plurality of conductive balls 160. At a side close to the first redistribution layer 150, the metal outer layer 162 of each of the conductive balls 160 is in contact with the first redistribution layer 150, and the metal inner core 161 is separated from the first redistribution layer 150 by the metal outer layer 162. At another side close to the second redistribution layer 180, the first contact surface 162a of the metal outer layer 162 and the second contact surface 161a of the metal inner core 161 of each of the conductive balls 160 are in contact with the second redistribution layer 180. Since the conductive balls 160 have excellent conductivity, reduction in transmission impedance may be facilitated.

As shown in FIG. 12, the inactive surface 132 of the first chip 130a, the inactive surface 132 of the second chip 130b, and the inactive surface 132 of the third chip 130c are respectively thermally coupled to the second redistribution layer 180 via the first metal stack 120a, the second metal stack 120b, and the third metal stack 120c, and the second redistribution layer 180 is thermally coupled to the heat dissipation base 190. The heat generated by the first chip 130a, the second chip 130b, and the third chip 130c during operation may be quickly conducted to the heat dissipation base 190 via the second redistribution layer 180, and then exported from the heat dissipation base 190, thus preventing the chip package structure 100 from being warped, delaminated, or cracked due to thermal stress, so that the chip package structure 100 has excellent heat dissipation, electrical properties, and reliability. In addition to accelerating heat dissipation, the heat dissipation base 190 may also have a grounding function.

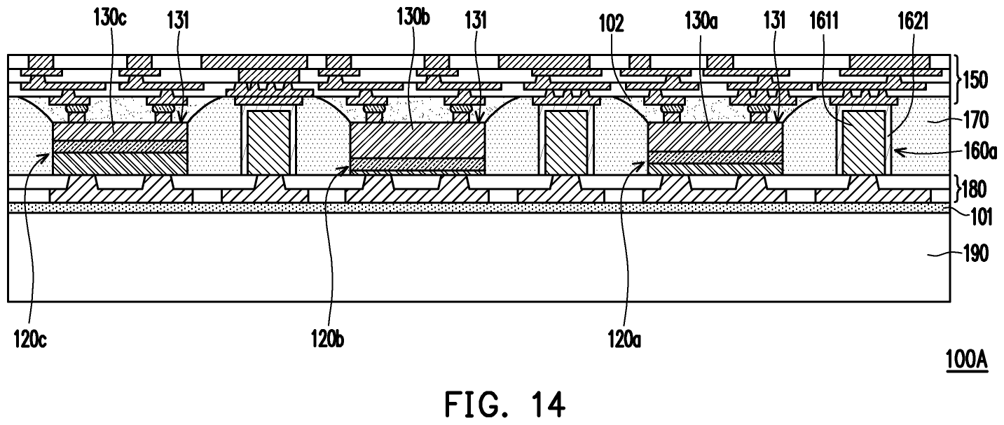

FIG. 14 is a schematic cross-sectional view of a chip package structure of another embodiment of the disclosure. Referring to FIG. 14, different from the chip package structure 100 of FIG. 12, a chip package structure 100A of the present embodiment uses a conductive pillar 160a as a conductive structure electrically connected to the first redistribution layer 150 and the second redistribution layer 180. Specifically, the conductive pillar 160a includes a metal inner core 1611 and a metal outer layer 1621 covering the metal inner core 1611, and the metal inner core 1611 is partially exposed to the metal outer layer 1621 to be in contact with the second redistribution layer 180. At a side close to the first redistribution layer 150, the metal outer layer 1621 is in contact with the first redistribution layer 150, and the metal inner core 1611 is separated from the first redistribution layer 150 by the metal outer layer 1621. At another side close to the second redistribution layer 180, both the metal outer layer 1621 and the metal inner core 1611 are in contact with the second redistribution layer 180. Since the conductive pillar 160a has excellent conductivity, reduction in transmission impedance may be facilitated.

The above embodiments are illustrated with three chips and three metal stacks, but the disclosure is not limited thereto. In other embodiments, the number of chips and the number of metal stacks of the chip package structure may be less than three, such as one or two, or greater than three.

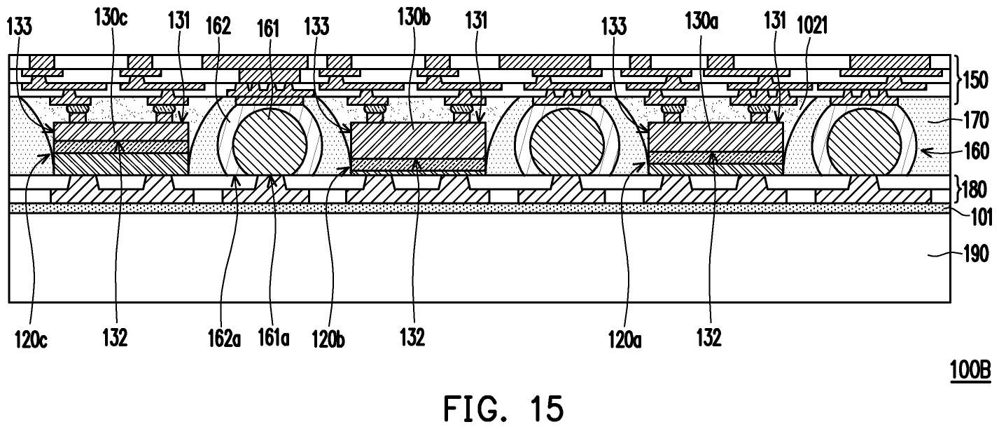

FIG. 15 is a schematic cross-sectional view of a chip package structure of another embodiment of the disclosure. Please refer to FIG. 15, a chip package structure 100B of the present embodiment is similar in structure design to the chip package structure 100 shown in FIG. 12, and the main difference between the two is: in the present embodiment, each of the chips also has a side surface 133 connected to the active surface 131, and an underfill layer 1021 further covers the side surface 133 of the chip and covers the metal stack.

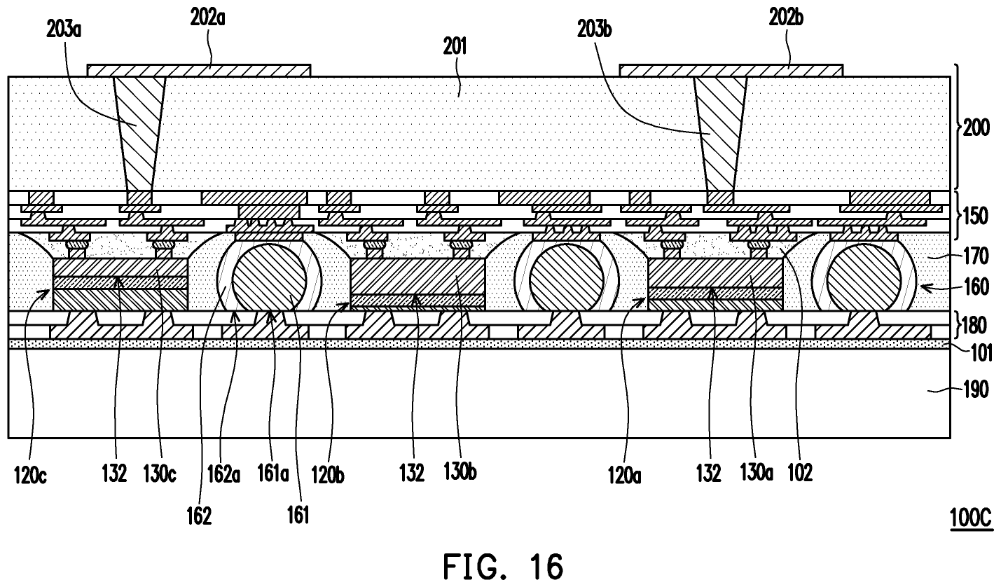

FIG. 16 is a schematic cross-sectional view of a chip package structure of another embodiment of the disclosure. Please refer to FIG. 16, a chip package structure 100C of the present embodiment is similar to the structure design of the chip package structure 100 shown in FIG. 12, and the main difference between the two is: in the present embodiment, the chip package structure 100C further includes a third redistribution layer 200 disposed on the first redistribution layer 150, and the first redistribution layer 150 is located between the encapsulant 170 and the third redistribution layer 200.

In detail, the third redistribution layer 200 includes a molding layer 201, at least two circuits 202a and 202b, and at least two conductive vias 203a and 203b. The molding layer 201 covers the first redistribution layer 150, and the two circuits 202a and 202b are disposed on the molding layer 201. In addition, the two conductive vias 203a and 203b penetrate through the molding layer 201. Moreover, the two circuits 202a and 202b are electrically connected to the first redistribution layer 150 via the two conductive vias 203a and 203b respectively.

For example, the molding layer 201 may be formed by a low dielectric constant and low dielectric loss molding material, and the encapsulant 170 may be formed by a silicon-containing molding material. Moreover, the two circuits 202a and 202b may respectively be a first antenna and a second antenna having a frequency different from that of the first antenna, but not limited thereto.

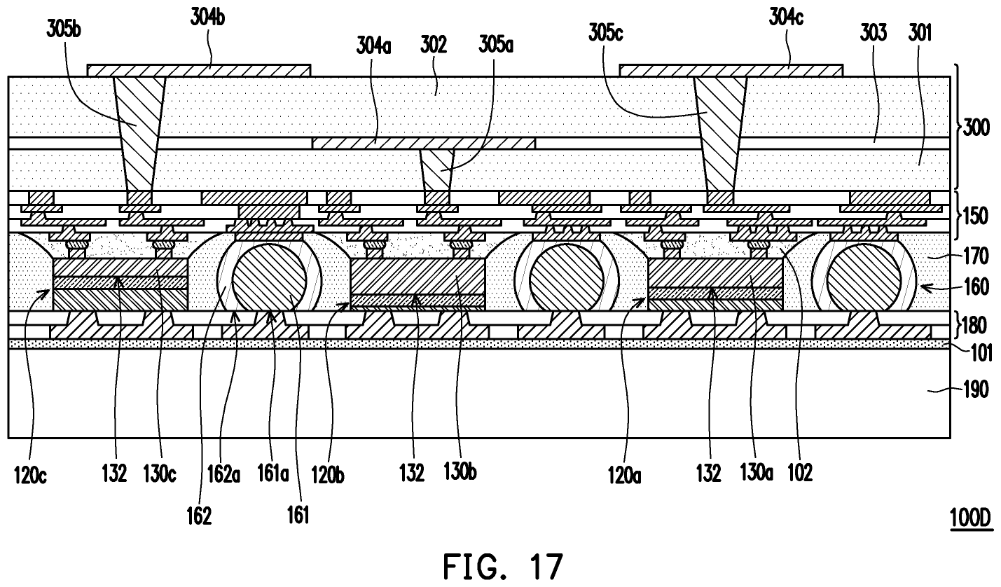

FIG. 17 is a schematic cross-sectional view of a chip package structure of another embodiment of the disclosure. Please refer to FIG. 17, a chip package structure 100D of the present embodiment is similar to the structure design of the chip package structure 100 shown in FIG. 12, and the main difference between the two is: in the present embodiment, the chip package structure 100D further includes a third redistribution layer 300 disposed on the first redistribution layer 150, and the first redistribution layer 150 is located between the encapsulant 170 and the third redistribution layer 300.

Specifically, the third redistribution layer 300 includes a first molding layer 301, a second molding layer 302, a dielectric layer 303, a first circuit 304a, a second circuit 304b, a third circuit 304c, a first conductive via 305a, a second conductive via 305b, and a third conductive via 305c. The first molding layer 301 covers the first redistribution layer 150, and the second molding layer 302 is disposed above the first molding layer 301. The dielectric layer 303 and the first circuit 304a are disposed between the first molding layer 301 and the second molding layer 302, wherein the first conductive via 305a penetrates through the first molding layer 301, and the first circuit 304a is electrically connected to the first redistribution layer 150 via the first conductive via 305a.

Moreover, the second circuit 304b and the third circuit 304c are disposed on the second molding layer 302, wherein the second conductive via 305b and the third conductive via 305c penetrate through the second molding layer 302, the dielectric layer 303, and the first molding layer 301, and the second circuit 304b and the third circuit 304c are electrically connected to the first redistribution layer 150 via the second conductive via 305b and the third conductive via 305c respectively.

For example, the first molding layer 301 and the second molding layer 302 may be formed by a low dielectric constant and low dielectric loss molding material, and the encapsulant 170 may be formed by a silicon-containing molding material. Moreover, the first circuit 304a, the second circuit 304b, and the third circuit 304c may respectively be a first antenna, a second antenna having a frequency different from the first antenna, and a third antenna having a frequency different from the second antenna, but not limited thereto.

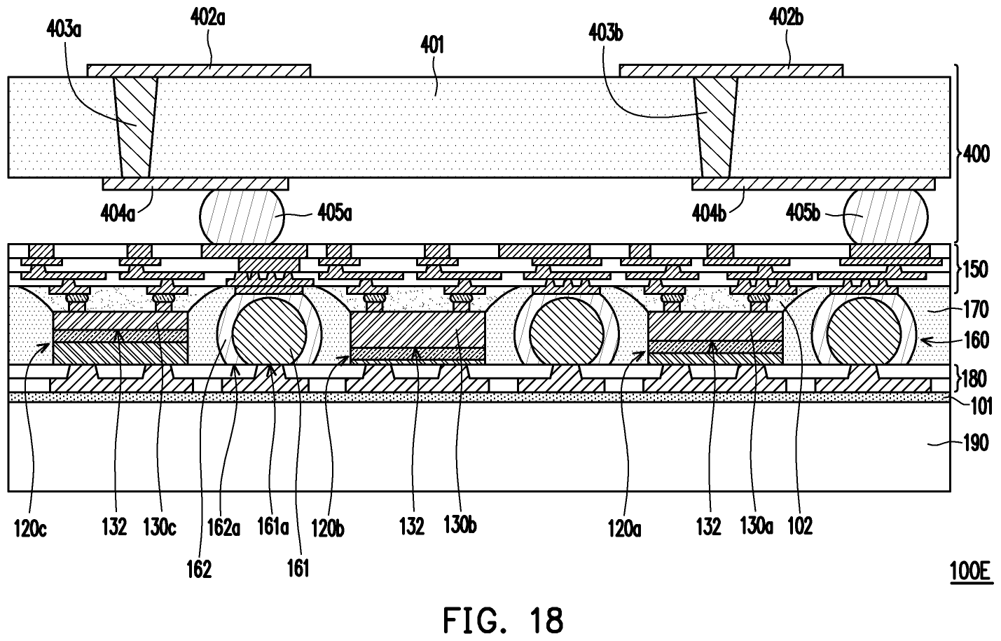

FIG. 18 is a schematic cross-sectional view of a chip package structure of another embodiment of the disclosure. Please refer to FIG. 18, a chip package structure 100E of the present embodiment is similar to the structure design of the chip package structure 100 shown in FIG. 12, and the main difference between the two is: in the present embodiment, the chip package structure 100E further includes a third redistribution layer 400 disposed on the first redistribution layer 150, and the first redistribution layer 150 is located between the encapsulant 170 and the third redistribution layer 400.

Specifically, the third redistribution layer 400 includes a molding layer 401, at least two circuits 402a and 402b, at least two conductive vias 403a and 403b, at least two conductive pads 404a and 404b, and at least two conductive balls 405a and 405b, and the molding layer 401 is disposed above the first redistribution layer 150. The two circuits 402a and 402b are disposed at a side of the molding layer 401, and the two conductive pads 404a and 404b are disposed at another side of the molding layer 401.

Moreover, the two conductive balls 405a and 405b are located between the first redistribution layer 150 and the two conductive pads 404a and 404b, and the two conductive vias 403a and 403b penetrate through the molding layer 401. The circuit 402a is electrically connected to the first redistribution layer 150 via the conductive via 403a, the conductive pad 404a, and the conductive ball 405a, and the circuit 402b is electrically connected to the first redistribution layer 150 via the conductive via 403b, the conductive pad 404b, and the conductive ball 405b.

For example, the molding layer 401 may be formed by a low dielectric constant and low dielectric loss molding material, and the encapsulant 170 may be formed by a silicon-containing molding material. The two circuits 402a and 402b may respectively be a first antenna and a second antenna having a frequency different from that of the first antenna, but not limited thereto. Moreover, the two conductive balls 405a and 405b may be solder balls or copper core solder balls, and in other examples, conductive pillars may be used instead of the conductive balls.

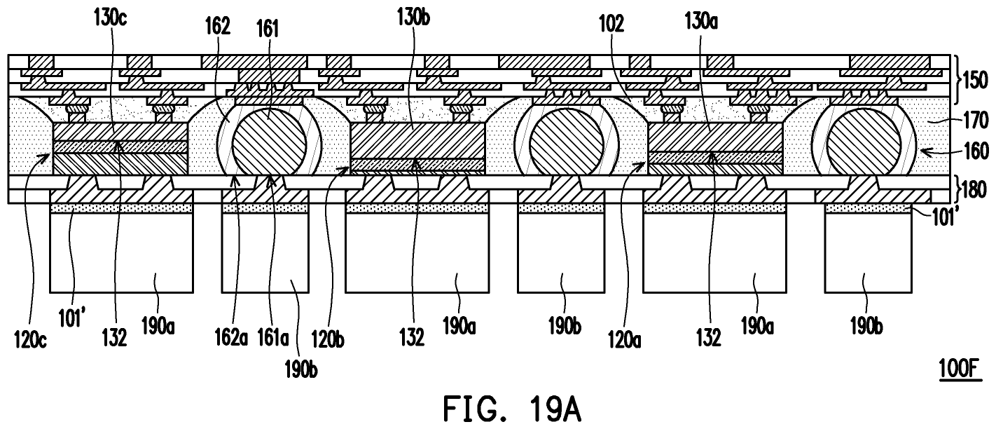

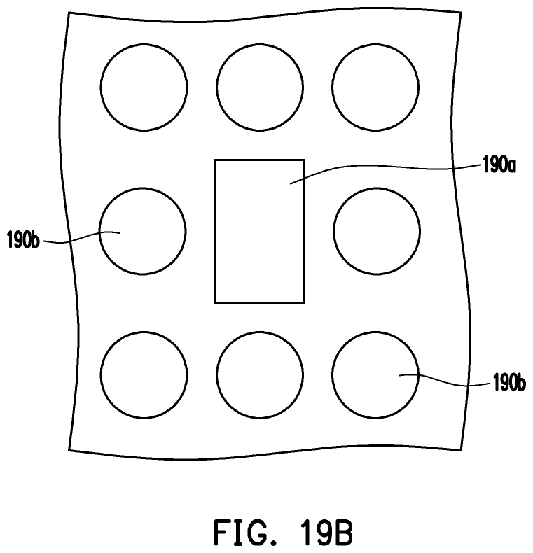

FIG. 19A is a schematic cross-sectional view of a chip package structure of another embodiment of the disclosure. FIG. 19B is a partial schematic top view of FIG. 19A. Please refer to FIG. 19A and FIG. 19B, a chip package structure 100F of the present embodiment is similar in structure design to the chip package structure 100 shown in FIG. 12, and the main difference between the two is: in the present embodiment, the heat dissipation base includes a plurality of heat dissipation portions 190a and a plurality of electrical transmission portions 190b. The plurality of heat dissipation portions 190a are respectively located opposite to the first chip 130a to the third chip 130c and thermally coupled to the second redistribution layer 180. Moreover, the plurality of electrical transmission portions 190b are located in the periphery of the plurality of heat dissipation portions 190a, wherein the plurality of electrical transmission portions 190b are respectively located opposite to the plurality of conductive structures (such as the conductive balls 160) and electrically connected to the second redistribution layer 180.

More specifically, the heat generated by the first chip 130a, the second chip 130b, and the third chip 130c during operation may be quickly conducted to the plurality of heat dissipation portions 190a via the second redistribution layer 180, and then dissipated outward by the plurality of heat dissipation portions 190a. Moreover, an internal electrical signal may be exported via the plurality of electrical transmission portions 190b or an external electrical signal may be imported via the plurality of electrical transmission portions 190b, and internal power may be exported via the plurality of electrical transmission portions 190b or external power may be imported via the plurality of electrical transmission portions 190b.

Please refer to FIG. 12 and FIG. 19A, the heat dissipation base 190 is bonded to the second redistribution layer 180 via the thermal interface material 101, and after patterning, the heat dissipation base 190 may form the plurality of heat dissipation portions 190a and the plurality of electrical transmission portions 190b, and the thermal interface material 101 may form a plurality of thermal interface materials 101′. Specifically, the plurality of heat dissipation portions 190a and the plurality of electrical transmission portions 190b are overlapped on the plurality of thermal interface materials 101′, and bonded to the second redistribution layer 180 via the plurality of thermal interface materials 101′.

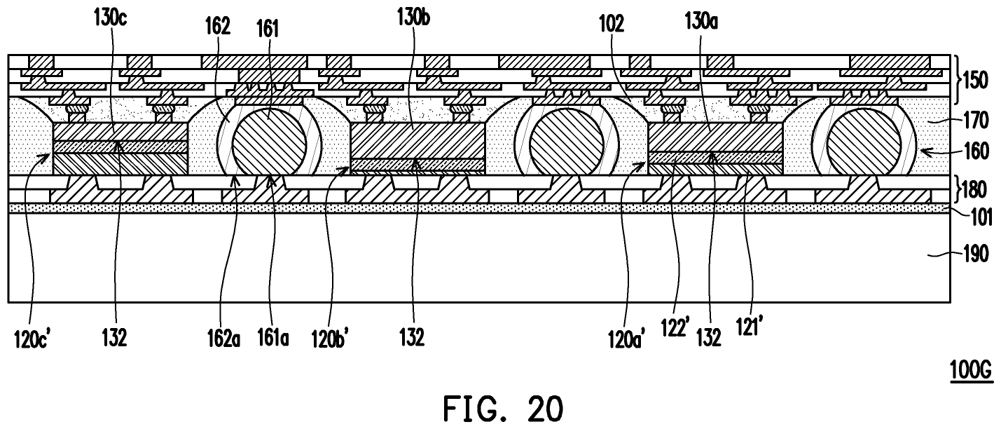

FIG. 20 is a schematic cross-sectional view of a chip package structure of another embodiment of the disclosure. Please refer to FIG. 20, a chip package structure 100G of the present embodiment is similar in structure design to the chip package structure 100 shown in FIG. 12, and the main difference between the two is: in the present embodiment, the metal stacks (such as the first metal stack 120a′, the second metal stack 120b′, and the third metal stack 120c′) are formed by a metal layer 121′ and a sintered material layer 122′, wherein the metal layer 121′ is located between the second redistribution layer 180 and the sintered material layer 122′, and the sintered material layer 122′ may be silver paste or copper paste bonded between the inactive surface 132 of the chip and the metal layer 121′ to improve the lattice mismatch between the chip and the metal layer 121′, so as to improve conduction efficiency and heat dissipation capability.

Based on the above, during the manufacturing process, the plurality of sacrificial layers having the same size may be used as an auxiliary tool for grabbing and transferring the plurality of chips, so as to improve the stability when grabbing the plurality of chips, and quickly and accurately transfer the plurality of chips onto the first redistribution layer, thus not only facilitating improvement in process efficiency, but also facilitating improvement in process reliability. Moreover, in the chip package structure of the disclosure, the inactive surface of each of the chips is thermally coupled to the second redistribution layer via the corresponding metal stack, and the second redistribution layer is thermally coupled to the heat dissipation base. Therefore, the heat generated by each of the chips during operation may be quickly conducted to the heat dissipation base via the second redistribution layer, and then exported from the heat dissipation base, thus preventing warping, delamination, or cracking of the chip package structure due to thermal stress, so that the chip package structure has excellent heat dissipation, electrical properties, and reliability.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A chip package structure, comprising:
a heat dissipation base;
a first redistribution layer;
a second redistribution layer disposed on the heat dissipation base and thermally coupled to the heat dissipation base, and the second redistribution layer is located between the first redistribution layer and the heat dissipation base;
a plurality of chips disposed between the second redistribution layer and the first redistribution layer and having different thicknesses, wherein each of the chips has an active surface facing the first redistribution layer and an inactive surface facing the second redistribution layer, and the active surfaces of the chips are electrically connected to the second redistribution layer;
a plurality of metal stacks disposed between the second redistribution layer and the inactive surfaces of the chips, wherein the inactive surfaces of the chips are thermally coupled to the second redistribution layer via the metal stacks, and the metal stacks have different thicknesses;
a plurality of conductive structures disposed between the second redistribution layer and the first redistribution layer and electrically connected to the second redistribution layer and the first redistribution layer, wherein each of the conductive structures comprises a metal inner core and a metal outer layer covering the metal inner core, and the metal inner core is partially exposed on the metal outer layer to be in contact with the second redistribution layer; and
an encapsulant filled between the second redistribution layer and the first redistribution layer.

2. The chip package structure of claim 1, wherein each of the metal stacks comprises a first metal layer and a second metal layer, the first metal layer is located between the second redistribution layer and the second metal layer, and the second metal layer is located between the first metal layer and the inactive surface of the corresponding chip.

3. The chip package structure of claim 2, wherein the first metal layers of the metal stacks have different thicknesses.

4. The chip package structure of claim 3, wherein a thickness of the first metal layer of one of the metal stacks connected to one of the thicker chips is less than a thickness of the first metal layer of another metal stack connected to another thinner chip.

5. The chip package structure of claim 3, wherein a total thickness of one of the chips and one of the metal stacks connected to each other is equal to a total thickness of another chip and another metal stack connected to each other.

6. The chip package structure of claim 2, wherein the second metal layers of the metal stacks have a same thickness.

7. The chip package structure of claim 2, wherein a material of the first metal layer of each of the metal stacks comprises copper, and a material of the second metal layer comprises tin.

8. The chip package structure of claim 1, wherein the metal outer layer of each of the conductive structures has a first contact surface in contact with the second redistribution layer, the metal inner core has a second contact surface exposed to the first contact surface, and the second contact surface is in contact with the second redistribution layer.

9. The chip package structure of claim 8, wherein the first contact surface of the metal outer layer of each of the conductive structures and the second contact surface of the metal inner core are coplanar.

10. The chip package structure of claim 8, wherein the first contact surface of the metal outer layer of each of the conductive structures surrounds the second contact surface of the metal inner core.

11. The chip package structure of claim 1, wherein the metal outer layer of each of the conductive structures is in contact with the first redistribution layer, and the metal inner core and the first redistribution layer are separated by the metal outer layer.

12. The chip package structure of claim 1, wherein each of the conductive structures is a conductive ball or a conductive pillar.

13. The chip package structure of claim 1, wherein a material of the metal inner core of each of the conductive structures is copper, and a material of the metal outer layer is tin.

14. The chip package structure of claim 1, wherein a material of the heat dissipation base comprises copper or silicon.

15. The chip package structure of claim 1, further comprising:
a plurality of underfill layers respectively disposed between the active surfaces of the chips and the first redistribution layer.

16. The chip package structure of claim 15, wherein each of the chips also has a side surface connected to the active surface, and the underfill layer further covers the side surface of the chip and covers the metal stack.

17. The chip package structure of claim 1, further comprising a third redistribution layer, wherein the third redistribution layer is disposed on the first redistribution layer, and the first redistribution layer is located between the encapsulant and the third redistribution layer.

18. The chip package structure of claim 17, wherein the third redistribution layer comprises a molding layer covering the first redistribution layer, at least two circuits disposed on the molding layer, and at least two conductive vias penetrating through the molding layer, and the two circuits are respectively electrically connected to the first redistribution layer via the two conductive vias.

19. The chip package structure of claim 17, wherein the third redistribution layer comprises a first molding layer covering the first redistribution layer, a second molding layer disposed above the first molding layer, a dielectric layer and a first circuit disposed between the first molding layer and the second molding layer, a second circuit and a third circuit disposed on the second molding layer, a first conductive via, a second conductive via, and a third conductive via, the first conductive via penetrates through the first molding layer, and the first circuit is electrically connected to the first redistribution layer via the first conductive via, the second conductive via and the third conductive via penetrate through the second molding layer, the dielectric layer, and the first molding layer, and the second circuit and the third circuit are electrically connected to the first redistribution layer via the second conductive via and the third conductive via respectively.

20. The chip package structure of claim 17, wherein the third redistribution layer comprises a molding layer disposed above the first redistribution layer, at least two circuits disposed at a side of the molding layer, at least two conductive vias penetrating through the molding layer, and at least two conductive pads and at least two conductive balls disposed at another side of the molding layer, and the two conductive balls are located between the first redistribution layer and the two conductive pads, and each of the circuits is electrically connected to the first redistribution layer via one of the conductive vias, one of the conductive pads, and one of the conductive balls.

21. The chip package structure of claim 1, wherein the heat dissipation base comprises a plurality of heat dissipation portions and a plurality of electrical transmission portions, the heat dissipation portions are respectively located opposite to the chips and thermally coupled to the second redistribution layer, and the electrical transmission portions are located in a periphery of the heat dissipation portions, wherein the electrical transmission portions are respectively located opposite to the conductive structures and electrically connected to the second redistribution layer.

22. The chip package structure of claim 1, wherein each of the metal stacks comprises a metal layer and a sintered material layer, wherein the metal layer is located between the second redistribution layer and the sintered material layer, and the sintered material layer is located between the metal layer and the inactive surface of the corresponding chip.

23. A manufacturing method of a chip package structure, comprising:
forming a plurality of metal stacks on a first carrier;
providing a plurality of chips having different sizes, wherein each of the chips has an active surface and an inactive surface opposite to the active surface, and the inactive surfaces of the chips are bonded to the metal stacks;
grinding a side of the first carrier opposite to the metal stacks, and cutting the first carrier to form a plurality of sacrificial layers bonded to the metal stacks, wherein the sacrificial layers have a same size;
forming a first redistribution layer on a second carrier;
transferring the corresponding metal stack and chip onto the first redistribution layer via each of the sacrificial layers, and bonding the active surfaces of the chips to the first redistribution layer;
forming a plurality of conductive structures on the first redistribution layer, wherein each of the conductive structures comprises a metal inner core and a metal outer layer covering the metal inner core;
forming an encapsulant on the first redistribution layer to cover the chips, the metal stacks, the sacrificial layers, and the conductive structures;
grinding a side of the encapsulant opposite to the first redistribution layer and removing the sacrificial layers, partially removing the metal stacks, and partially removing the metal inner core and the metal outer layer of each of the conductive structures, so that the metal stacks have different thicknesses, and partially exposing the metal inner core of each of the conductive structures to the metal outer layer;
forming a second redistribution layer on the encapsulant so that the metal stacks are thermally coupled to the second redistribution layer, and the metal inner core in each of the conductive structures exposed to the metal outer layer is in contact with the second redistribution layer;
removing the second carrier; and
bonding a heat dissipation base to a side of the second redistribution layer opposite to the encapsulant.

24. The manufacturing method of the chip package structure of claim 23, wherein the chips have different thicknesses.

25. The manufacturing method of the chip package structure of claim 23, wherein each of the sacrificial layers has a surface opposite to the corresponding metal stack, and an area of the surface is greater than an area of the inactive surface of the corresponding chip.

26. The manufacturing method of the chip package structure of claim 23, wherein a width of each of the sacrificial layers is greater than a width of the corresponding metal stack.

27. The manufacturing method of the chip package structure of claim 23, wherein a width of each of the sacrificial layers is greater than a width of the corresponding chip.

28. The manufacturing method of the chip package structure of claim 23, wherein each of the metal stacks comprises a first metal layer and a second metal layer, and the second metal layer is located between the first metal layer and the inactive surface of the corresponding chip.

29. The manufacturing method of the chip package structure of claim 28, wherein partially removing the metal stacks is grinding the first metal layers, and the first metal layers have different thicknesses after grinding.

30. The manufacturing method of the chip package structure of claim 28, wherein the second metal layers of the metal stacks have a same thickness.

31. The manufacturing method of the chip package structure of claim 28, wherein partially removing the metal stacks is grinding the first metal layers, and the first metal layers have different removal amounts.

32. The manufacturing method of the chip package structure of claim 31, wherein according to the different thicknesses of the chips, the first metal layers have different removal amounts, and a removal amount of the first metal layer of one of the metal stack connected to a thicker chip is greater than a removal amount of the first metal layer of another metal stack connected to another thinner chip.

33. The manufacturing method of the chip package structure of claim 28, wherein the metal outer layer and the metal inner core of each of the conductive structures after grinding respectively form a first contact surface and a second contact surface, and the first contact surface and the second contact surface are coplanar.

34. The manufacturing method of the chip package structure of claim 33, wherein when forming the second redistribution layer on the encapsulant, the first contact surface of the metal outer layer of each of the conductive structures and the second contact surface of the metal inner core are in contact with the second redistribution layer.

35. The manufacturing method of the chip package structure of claim 23, further comprising:
forming a plurality of underfill layers between the active surfaces of the chips and the first redistribution layer after the active surfaces of the chips are bonded to the first redistribution layer.

36. A chip package structure, comprising:
a heat dissipation base;
a first redistribution layer;
a second redistribution layer disposed on the heat dissipation base and thermally coupled to the heat dissipation base, and the second redistribution layer is located between the first redistribution layer and the heat dissipation base;
a chip disposed between the second redistribution layer and the first redistribution layer, wherein the chip has an active surface facing the first redistribution layer and an inactive surface facing the second redistribution layer, and the active surface is electrically connected to the second redistribution layer;
a metal stack disposed between the second redistribution layer and the inactive surface, and the inactive surface is thermally coupled to the second redistribution layer via the metal stack;
a plurality of conductive structures disposed between the second redistribution layer and the first redistribution layer and electrically connected to the second redistribution layer and the first redistribution layer, wherein each of the conductive structures comprises a metal inner core and a metal outer layer covering the metal inner core, and the metal inner core and the metal outer layer are partially removed so that the metal inner core is partially exposed on the metal outer layer to be in contact with the second redistribution layer; and
an encapsulant filled between the second redistribution layer and the first redistribution layer.
